(19) United States
(12) Patent Application Publication
(10) Pub. No.: US 2015/0013746 A1
(43) Pub. Date: Jan. 15, 2015

(54) Photovoltaic System with Embedded Energy Storage Device

(71) Applicant: Alexander Mikhailovich Shukh, San Jose, CA (US)

(72) Inventor: Alexander Mikhailovich Shukh, San Jose, CA (US)

(21) Appl. No.: 14/328,673

(22) Filed: Jul. 10, 2014

Related U.S. Application Data
(60) Provisional application No. 61/844,593, filed on Jul. 10, 2013.

(51) Int. Cl. H01L 31/04

(52) U.S. Cl. CPC H01L 31/04
USPC 136/244

(57) ABSTRACT

One embodiment of a photovoltaic system comprises a solar cell, a blocking device and a magnetic capacitor, wherein the solar cell and the magnetic capacitor are stacked over each other, and wherein the solar cell and the magnetic capacitor are electrically coupled to each other through the blocking device. Other embodiments the photovoltaic system are described and shown.

### CROSS-REFERENCE TO RELATED APPLICATIONS

This application claims benefit of U.S. Provisional Patent Application Ser. No. 61/844,593, filed on Jul. 10, 2013, the entire content of which is incorporated herein by reference.

### FEDERALLY SPONSORED RESEARCH

Not applicable.

### SEQUENCE LISTING OF PROGRAM

Not applicable.

### RELEVANT PRIOR ART

U.S. Pat. No. 6,137,048, Oct. 24, 2000—Wu et al.

U.S. Pat. No. 7,821,771 B2, Oct. 26, 2010—Lai.

U.S. Patent Application Publication No. US 2008/0174933 A1, Jul. 24, 2008—Lai et al.

U.S. Patent Application Publication No. US 2008/0174936 A1, Jul. 24, 2008—Lai et al.

U.S. Patent Application Publication No. US 2009/0090946 A1, Apr. 9, 2009—Lai et al.

U.S. Patent Application Publication No. US 2010/0214718 A1, Aug. 26, 2010—Yeh

U.S. Patent Application Publication No. US 2011/0242726 A1, Oct. 6, 2011—Chan

### BACKGROUND

Solar cells (or photovoltaic devices) utilize specific properties of semiconductors to convert energy of visible and near visible light of the sun into electrical energy. This conversion results from absorption of the radiant energy in semiconductor materials which frees some valence electrons, thereby generating electron-hole pairs. Conventional solar cells usually include p-n (or p-i-n) junction formed near surface of light incidence. When sunlight striking solar cells creates charge carriers, an intrinsic electric field of the p-n junction pushes new electrons to one side of the junction and new holes to the other. This sorting-out process is what drives the charge carriers in an electric circuit. The energy required to generate electron-hole pairs in a semiconductor material is referred to as a band gap energy, which in general is the minimum energy needed to excite an electron from the valence band to the conduction band.

Solar cells can typically be categorized into two types based on the light absorbing material used: bulk or semiconductor wafer-based solar cells and thin film solar cells. The wafer-based solar cells use mono-, poly- or multi-crystalline silicon (c-Si, poly-Si or mc-Si, respectively), crystalline semiconductor of III-V groups (GaAs, InGaP, and similar) and other materials. The thin-film solar cells can be made of semiconductor thin films such as amorphous and polycrystalline silicon (α-Si and poly-Si, respectively), cadmium telluride (CdTe), cadmium sulfide (CdS), copper indium diselenide (CuInSe₂), copper indium diselenide (CuInGaSe₂), and others. The thin film solar cells can be formed on various substrates including glass, plastic and others. Besides, there are several emerging solar cell technologies based on use of organic dyes, organic polymers, quantum dots, and others.

FIG. 1 illustrates a schematic diagram of a photovoltaic system (circuit) 10 comprising a solar cell 11 electrically coupled to a battery 12 through a diode 13 serving as a blocking device, The solar cell 11 can comprise p-type semiconductor layer 14 and n-type semiconductor layer 15 forming p-n junction 19. To increase efficiency of sunlight use the solar cell 11 can comprise an antireflection layer 18 disposed above the semiconductor layer facing the sunlight. Besides, the solar cell 11 can comprise back 16 and front 17 metal contacts. The front contact (facing the sun) 17 can be designed as a grid with fingers reaching to every parts of the cell's surface. The front contact 17 can combine a low resistance with low shading effect. The back and front contacts can be made of aluminum (Al), molybdenum (Mo) or other materials. In some cases the front contact 17 can be made of transparent conducting oxide (TCO) that combines an optical transparency with a high electrical conductivity, such as SnO₂, InO₂, ZnO and others, Through the contacts 16 and 17 the solar cell 11 can be electrically connected into a solar cells array or to the battery.

The antireflection layer 18 can substantially increase efficiency of the solar cell. The layer 18 can provide a reduction of sunlight reflection by a top surface of the cell 11. The antireflection layer 18 can be made of silicon monoxide (SiO). Adding an additional antireflection layer made of other materials can reduce the reflection even more. Another way to reduce the reflection is to texture the top surface of the solar cell. The highest efficiency cell typically use a well-designed double-layer antireflection coating with a textured top surface.

Several solar cells can be electrically connected to each other in series or in parallel to form a solar module or panel and to meet voltage and current requirements. However the solar cells suffer from several disadvantages. For example, they need an energy storage device, such as a battery, and a blocking device or charge controller protecting the battery from overcharge or discharge. The blocking device 13 can prevent a current flow from the battery 12 to the solar cell 11 at nighttime. It can be made of a semiconductor diode.

Batteries are not only energy storage devices. They also can serve as a power conditioner. By being a part of the electrical circuit, the battery 12 can keep an electrical load nearly constant, hence the solar cell 11 can operate closer to its optimum power output. Conventional batteries are bulky and should be stored in a special place remote from the solar cells. Besides they have memory problem of being partially charged/discharged and decreasing overall performance. These obstacles substantially limit solar cells application in mobile computing and communication devices.

Accordingly, there is a need for a solar cell with an embedded energy storage device having a significant capacitance and low current leakage.

### SUMMARY

It is therefore an objective of the present application to provide a photovoltaic system with an embedded energy storage device.

According to one embodiment of the present application a photovoltaic system comprises a solar cell, a blocking device and a magnetic capacitor, wherein the solar cell and the magnetic capacitor are stacked over each other, and wherein the solar cell and the magnetic capacitor are electrically coupled to each other through the blocking device.

### BRIEF DESCRIPTION OF THE DRAWINGS

These and other features, aspects, and advantages of the present disclosure will become better understood with regard to the following description, accompanying drawings and appended claims, where:

FIG. 1 is a schematic diagram of a conventional photovoltaic system with a battery as an energy storage device.

FIG. 2 is a schematic diagram of a photovoltaic system with an embedded magnetic capacitor according to the present application.

FIGS. 3A and 3B illustrate schematic sectional diagrams of a crystalline solar cell with an embedded magnetic capacitor according to an embodiment of the present application.

FIGS. 4A and 4B illustrate schematic section diagrams of a thin film solar cell with an embedded magnetic capacitor according to another embodiment of the present application.

FIGS. 5A and 5B show schematic sectional diagrams of a magnetic capacitor with in-plane magnetization direction according to the present application.

FIG. 6 shows a schematic sectional diagram of a magnetic capacitor with a perpendicular magnetization direction according to the present application.

FIGS. 7 and 7B show schematic sectional diagrams of multi-sectional magnetic capacitors comprising in-plane magnetic materials with in-series and parallel sections coupling according to yet another embodiment of the present application.

FIG. 8 shows a schematic sectional diagram of a multi-sectional capacitor comprising perpendicular magnetic materials according to still another embodiment of the present application.

### DETAILED DESCRIPTION

Reference will now be made in detail to the embodiments of the present application, examples of which are illustrated in the accompanying drawings. A numerical order of the embodiments is random. Wherever possible, the same reference numbers are used in the drawings and the description to refer to the same or like parts.

All figures are drawn to ease explanation of basic teachings of the present application only. The extensions of the figures with respect to number, position, relationship, and dimensions of the parts to form the embodiment will be explained or will be within the skill of the art after the following description has been read and understood.

Use of conventional capacitors as energy storage devices is limited by their relatively low capacitance and leakage current decreasing overall performance. A conventional capacitor (or condenser) comprises two parallel conductive plates separated from each other by layer of an isolative material. The capacitance of the capacitor can be calculated using an equation (1):

C=ε₀εᵣA/d, (1)

wherein C is the capacitance of the capacitor, ε₀ =8.85·10⁻¹² F/m is a dielectric constant of free space (or vacuum permittivity), εᵣ is a relative dielectric constant (or relative permittivity) of the isolative material disposed between the conductive plates, A is an overlaying area of the parallel conductive plates, and d is a distance between the conductive plates.

The equation (1) suggests that the capacitance C of the capacitor is proportional to the area A of the parallel conductive plate, relative permittivity εᵣ of the isolative material disposed between the conductive plates, but inverse proportional to the distance d between the conductive plates that is frequently equal to the thickness of the dielectric layer. The layer of the isolative material can be made of dielectric or semiconductor materials.

The relative dielectric constant of the isolative materials varies in a broad range from 1 for vacuum to several thousands, for example, for barium titanate BaTiO₃. However, this material is not cheap, requires special technology of deposition, and its permittivity is very sensitive to temperature.

The permittivity of the traditional dielectric and semiconductor materials used in electronic and semiconductor industries, such as TiO₂, ZnO, SnO₂, SiC, Al₂O₃, SiO₂, Ta₂O₅, ZrO₂, HfO₂, Si₃N₄, La₂O₃, ZrSiO₄, HfSiO₄, SrTiO₃, TiₓAl₁₋ₓO_{y}, HfₓAl₁₋ₓO_{y}, PbZnTiO_{X}, PbLaTiO_{X} and others, can be substantially increased by positioning the dielectric or semiconductor layer between two magnetic layers substantially exchange coupled to each other.

FIG. 2 shows a schematic diagram of a photovoltaic system 20 according to the present application. The system 20 can include a solar cell 11 electrically coupled to a magnetic capacitor 22 through a diode 13 serving as a blocking device. The blocking device 13 can comprise a transistor. The electrical energy produced by the solar cell 11 can be used by a load 29. The solar cell 20 can comprise a p-n junction 19 formed by a p-type semiconductor substrate (layer) 14 having a direct contact with an n-type semiconductor layer 15. The front side of the n-type semiconductor layer 15 facing a light source can be covered with an antireflection layer 18. Back 16 and front 17 metal contact layers provide low resistance electrical coupling of the solar cell 11 to the energy storage capacitor 22.

The magnetic capacitor 22 can comprise a first conductive plate 27, a second conductive plate 28, a layer of an isolative material 25 made of a dielectric or semiconductor and disposed between the conductive plates. The isolative layer 25 can be separated from the conductive plates 27 and 28 by magnetic layers 24 and 26, respectively. The magnetic layer 24 can be disposed between the conductive plate 27 and the isolative layer and can have a direct contacts with the layer 25. Similarly, the magnetic layer 26 can be disposed between the isolative layer 25 and the conductive plate 28 and can have a direct contact with the layer 25. The magnetic layers 24 and 26 are magnetically exchange coupled to each other through the isolative layer 25. The magnetic layers 24 and 26 can be made of a magnetic material having in-plane or perpendicular magnetization direction. The magnetization directions in the layers 24 and 26 are shown by solid arrows. The magnetization directions in the layers 24 and 26 can be anti-parallel to each other. A mutual orientation of the magnetization directions in the magnetic layers 24 and 26 depends on type of an exchange coupling (ferromagnetic or anti-ferromagnetic) between the magnetic layers through the thin layer of the isolative material 25. The anti-parallel mutual orientation of magnetization directions corresponds to the anti-ferromagnetic coupling. Respectively, the parallel orientation of the magnetization directions corresponds to the ferromagnetic coupling between the layers 24 and 26. Type of exchange coupling and its strength substantially depends on thickness and material properties of the layer 25. The anti-parallel direction of magnetizations in the magnetic layers can provide a substantial reduction of a leakage current compared to that of the parallel magnetizations orientation.

The exchange coupling between the magnetic layers can change substantially a permittivity of the isolative layer 25. The permittivity of the layer can be increased by more than thousand times providing a substantial capacitance increase of the magnetic capacitor. An interaction with magnetic layers having spin-polarized electrons may increase substantially a polarization of the isolative material made of an dielectric or semiconductor. That can result in significant increases of electrical charges accumulation at magnetic/insulator interfaces. The permittivity of the isolative layer 25 in the magnetic capacitor can depend on a strength of the exchange coupling between the magnetic layers, thickness and spin polarization of the magnetic layers, their crystalline structure, roughness of the interfaces between the magnetic and isolative layers, properties of the isolative layer material and other parameters. The magnetic layers 24 and 26 may have a multilayer structure with a magnetic material having a substantial spin polarization being disposed adjacent to the isolative layer 25.

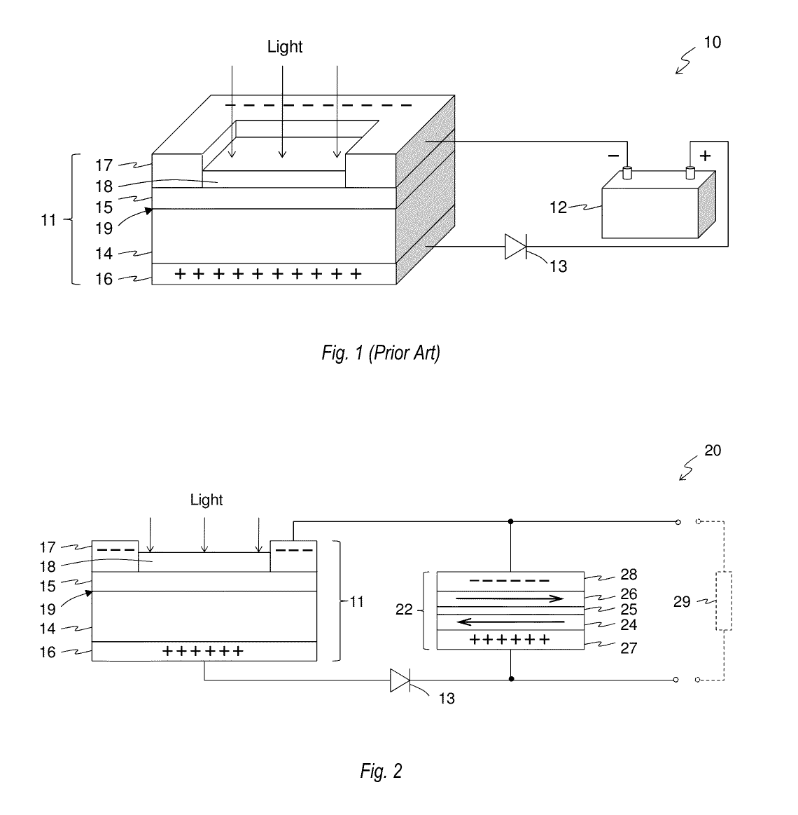

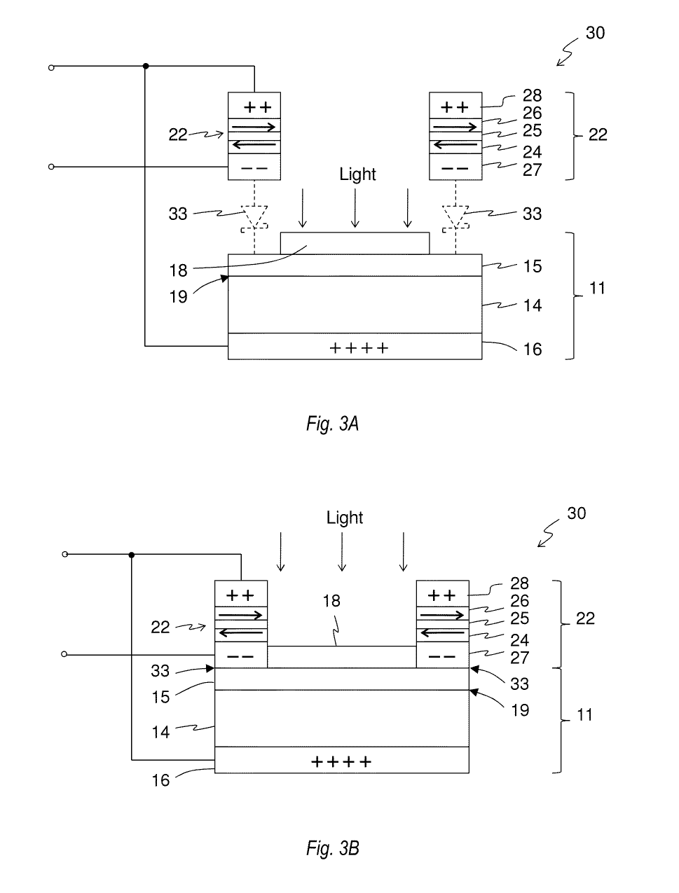

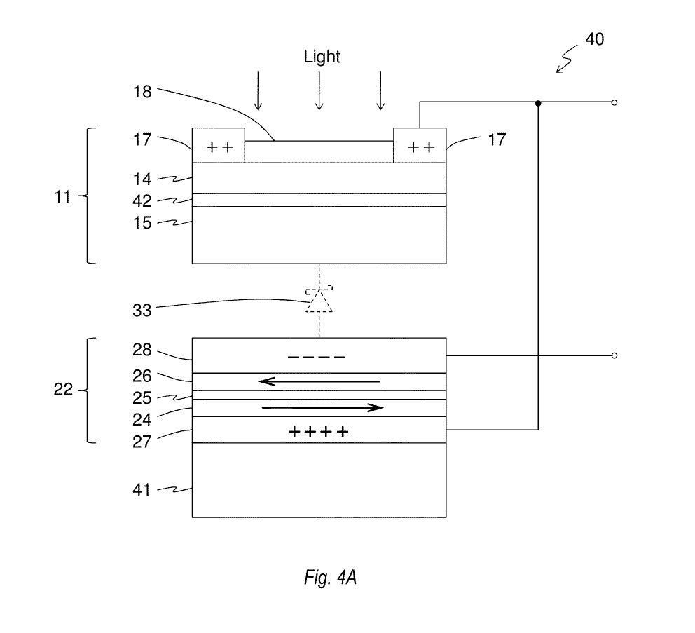

FIGS. 3A and 3B show schematic sectional diagrams of a crystalline solar cell with an embedded magnetic capacitor 30 according to an embodiment of the present application. The magnetic capacitor 22 can be disposed on a top surface of the solar cell 11 facing the sunlight. The front metal contact 17 of the solar cell 11 (see FIGS. 1 and 2) can be replaced by the magnetic capacitor 22. The capacitor 22 is electrically coupled to the n-type semiconductor layer 15 through the first conductive layer 27. A contact between the n-type semiconductor layer 15 and the conductive layer 27 can form a Schottky diode 33 (shown by dashed line). The Schottky diode 33 can serve as a blocking device preventing the capacitor 22 from discharge during a nighttime. The first conductive plate 27 can accumulate negative electrical charges of the n-type semiconductor layer 15. Respectively, the second conductive plate 28 can accumulate the positive charges of the p-type semiconductor substrate (layer) 14. The second conductive plate 28 of the magnetic capacitor 22 can be electrically coupled to a back metal contact 16 of the solar cell 11 which has a direct contact with p-type semiconductor layer 14 made of a crystalline semiconductor substrate, for example Si. The solar cell 11 can have single or multiple p-n junctions design. The magnetic capacitor 22 can be disposed on an opposite side of the semiconductor substrate 14 and can cover entire surface of the substrate. Moreover, the magnetic capacitors 22 can be disposed on both sides of the semiconductor substrate (layer) 14 being electrically coupled to each other.

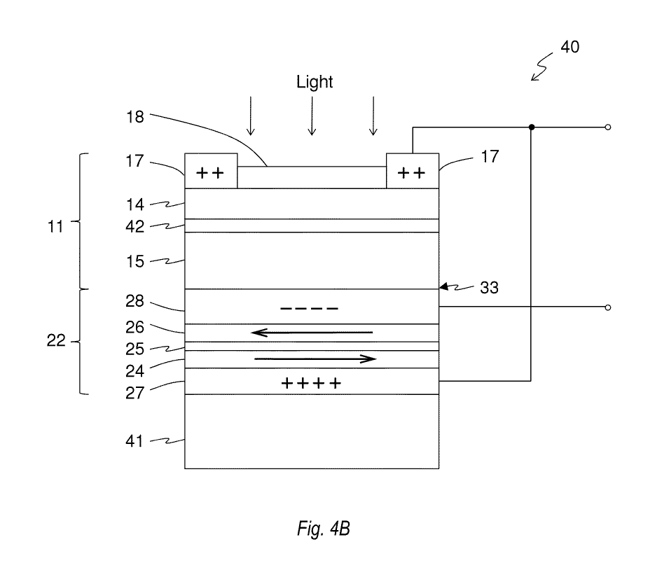

FIGS. 4A and 4B show schematic sectional diagrams of a thin film solar cell with an embedded magnetic capacitor 40 according to another embodiment of the present application. For illustrative purpose only the magnetic capacitor 22 (see FIG. 2) and thin film solar cell 11 are formed on a glass substrate 41. The solar cell 11 can be made of a polycrystalline silicon (poly-Si). The solar cell 11 can comprise a p-i-n junction formed by a n-type semiconductor layer 15, i-type semiconductor layer 42, and a p-type semiconductor layer 14. The n-type layer 15 can have a direct contact with the second conductive plate 28 and can produce a Schottky diode 33. The first conductive plate 27 can be eclectically coupled to the front electrode 17 of the solar cell 11. The thin film solar cell 11 can have other designs and can be made of other materials.

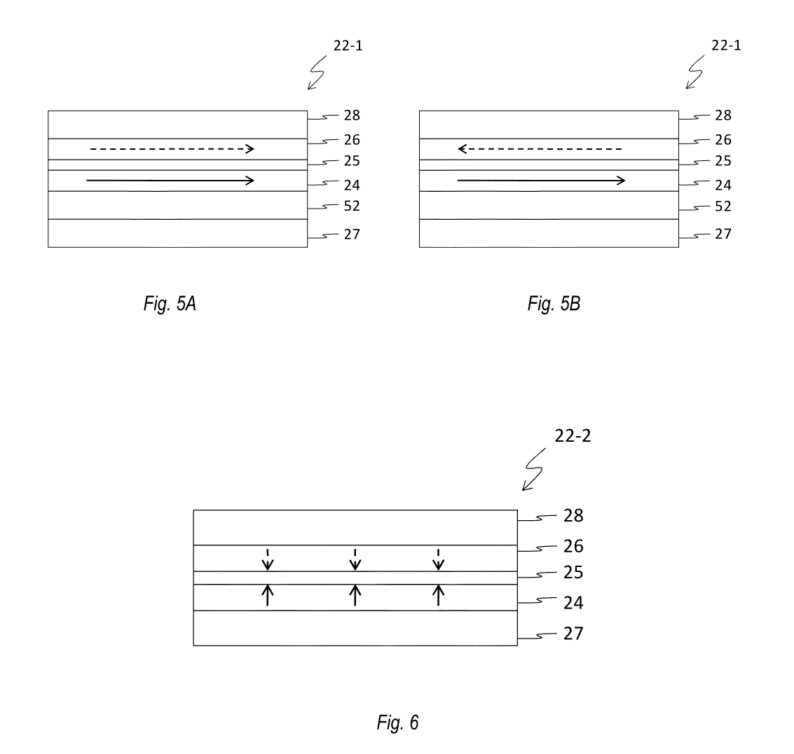

A magnetic capacitor can use magnetic materials with in-plane or perpendicular magnetization direction (magnetic anisotropy). FIGS. 5A and 5B illustrate schematic sectional diagrams of a magnetic capacitor comprising in-plane magnetic materials. The capacitor 22-1 shown in FIG. 5A comprises the magnetic layers 24 and 26 having a substantial spin polarization and a parallel magnetizations direction in the adjacent magnetic layers 24 and 26 (shown by solid and dashed arrows, respectively). One magnetic layer, for example the layer 24 can have a coercivity substantially higher than that of the layer 26. The magnetization direction of the layer 24 (shown by a solid arrow) can be fixed. The magnetization direction of the layer 26 (shown by a dashed arrow) can be reversible. The capacitor 22-1 can further comprise an anti-ferromagnetic layer 52 having a substantial exchange coupling with the magnetic layer 24. The anti-ferromagnetic coupling between the layers 24 and 52 can fix the magnetization direction of the magnetic layer 24. The anti-ferromagnetic layer 52 can be disposed adjacent to the magnetic layer 26 to produce the anti-ferromagnetic exchange coupling with the layer 26. That can result in providing the layer 26 with the fixed magnetization direction. Respectively, the magnetic layer 24 can have the reversible magnetization direction (or low coercivity). The coercivity of the magnetic layer comprising the reversible magnetization direction can be of about 100 Oe. The coercivity of the magnetic layer comprising the fixed magnetization direction can be of about 1000 Oe.

The magnetic capacitor 22-1 shown in FIG. 5B has an anti-parallel orientation of the magnetization directions in the magnetic layers 24 and 26. The anti-parallel orientation of the magnetizations direction in the adjacent magnetic layers 24 and 26 can provide a low leakage current through the isolative layer 25. This is essential for energy storage in the capacitor 22. The isolative layer 25 can have a single layer or multilayer structure, such as TiO₂, Ta₂O₅, SiN₃/CoFe/SiN₃, Ti/TiO₂/Ti, Ru/TiO₂/Ru, Ru/TaₓO_{y}/Ru, Cu/CuₓO/Cu, Al₂O₃/HfO₂/Al₂O₃ and others. It can be made of dielectric or semiconductor materials, such as Ta₂O₅, SiO, HfO₂ and similar, or Si, C, SiC, poly-Si, GaAs, Cu₂O, TiO₂, ZnO and similar. The magnetic layers 24 and 26 can be made of Co, Fe, CoFe, CoFeB, NiFe, CoFeV, FeV and similar material, having a substantial spin polarization.

The capacitor 22-1 shown in FIG. 5B with the parallel orientation of the magnetization directions in the magnetic layers 24 and 26 can have a leakage current through the isolative layer 25 that can be of about five times higher than that of the capacitor 22-1 shown in FIG. 5A comprising the anti-parallel orientation of the magnetization directions of the magnetic layers. The mutual orientation of the magnetization directions in the magnetic layers 24 and 26 can be changed from parallel to anti-parallel and vice verse by applying an external magnetic field to the capacitor 22-1, by passing a spin-polarized current having a density of about 3·10⁶ A/cm² through the isolative layer 25, or by a combination of the external magnetic field with the spin-polarized current.

FIG. 6 shows a schematic sectional diagram of a magnetic capacitor 22-2 comprising magnetic layers 24 and 26 having a perpendicular magnetization direction (magnetic anisotropy). The magnetic capacitor 22-2 can have an anti-parallel or parallel orientation of the magnetization directions in the adjacent magnetic layers 24 and 26. One of the magnetic layers, for example the layer 24 can comprise a fixed magnetization direction (shown by a solid arrow). Respectively, the layer 26 can have a reversible magnetization direction (shown by a dashed arrow). The magnetic layers 24 and 26 can have a single layer or multilayer structure, for example the layers 24 and 26 can be made of CoPt layer, (CoFe/Pt)n laminates, CoFe/GdFeCo bilayer or similar materials comprising a perpendicular anisotropy and a substantial spin polarization. The ferromagnetic layers of CoFe, Co and similar having the substantial spin polarization can be in a direct contact with the isolative layer 25.

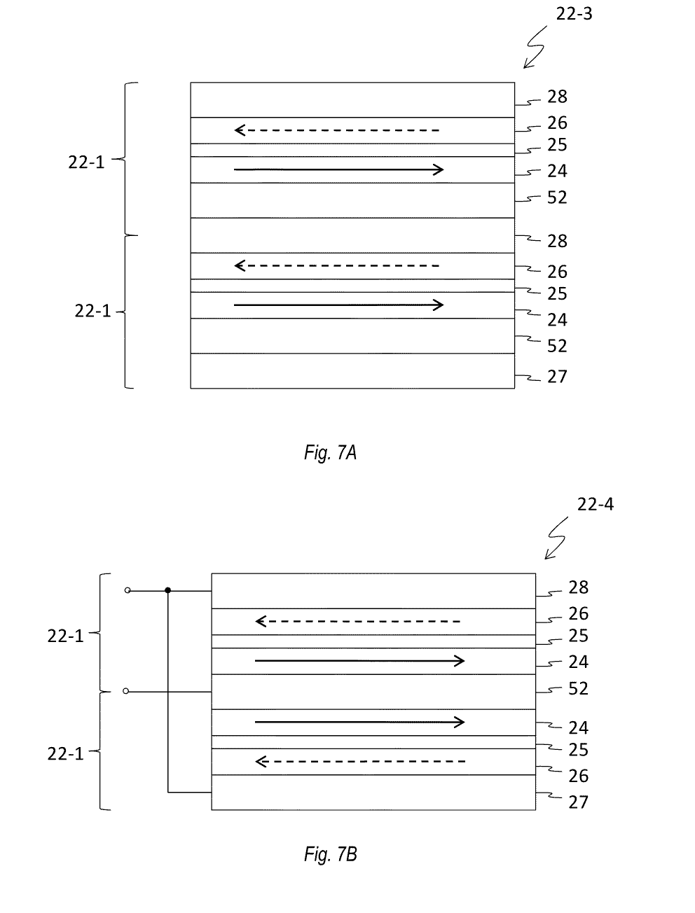

The capacitor 22 can have a multi-sectional design comprising several capacitors (sections) stacked above each other and electrically coupled to each other in series or in parallel. FIGS. 7A and 7B show schematic sectional diagrams of embodiments of the multi-sectional magnetic capacitor 22-3 and 22-4 with sections 22-1, coupled to each other in series and in parallel, respectively.

The multi-sectional capacitor 22-3 (FIG. 7A) comprises two sections 22-1 connected in series to each other. The capacitor 22-3 can comprise two anti-ferromagnetic layers 52 (one layer per section). The conductive layer 28 can serve both as the top conductive layer of the bottom section 22-1 and as the bottom conductive layer of the top section 22-1.

The sections 22-1 of the multi-sectional capacitor can be coupled to each other in parallel (FIG. 7B). The bottom and top sections 22-1 of the capacitor 22-4 can be separated from each other by the anti-ferromagnetic layer 52 made of a conductive alloy, for example IrMn. The anti-ferromagnetic layer 52 can fixed magnetization directions (solid arrows) of the magnetic layers 24 by means of anti-ferromagnetic exchange coupling. The magnetic layers 26 of the bottom and top sections 22-1 that are not exchange coupled with the anti-ferromagnetic layer 52 can have a reversible magnetization directions (shown by dashed arrows). The magnetic layers of the different sections 22-1 having similar magnetization direction can be electrically coupled to each other. For example, the magnetic layers 24 having the fixed magnetization directions (shown by solid arrows) are coupled to each other. Respectively, the magnetic layers 26 comprising the reversible magnetization direction are coupled to each other. Number of sections in the multi-sectional capacitor can be any.

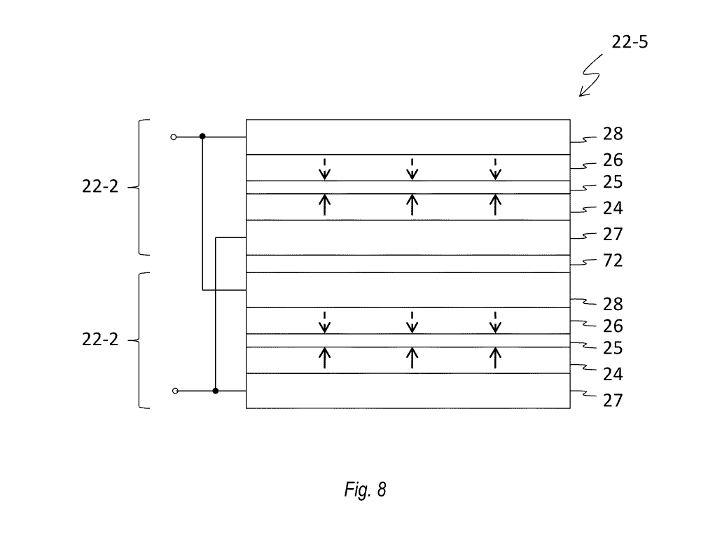

FIG. 8 shows a schematic sectional diagram of a magnetic capacitor 22-5 comprising two sections 22-2 (see FIG. 6) which are in parallel coupled to each other. The magnetic layers 24 and 26 of the capacitor 22-5 comprises a perpendicular magnetization direction. The magnetic layers 24 can have a fixed magnetization direction (shown by solid arrows) and can comprise magnetic materials having a coercivity of about 2000 Oe. The magnetic layers 26 can have a reversible magnetization direction (shown by dashed arrows). The magnetic layers 26 can comprise magnetic materials having a substantially lower coercivity than that of the magnetic layers 24, for example of about 200 Oe. The sections 22-2 of the capacitor 22-5 can be electrically isolated from each other by a spacer layer 72 made of an isolative material, for example SiO₂. The magnetic layer 24 having the fixed magnetization direction of the bottom and top sections 22-2 can be electrically coupled to each other. Respectively, the magnetic layers 26 having the reversible magnetization direction can be electrically coupled to each other. The capacitor 22-5 can use the magnetic sections 22-1 comprising magnetic materials with in-plane magnetization direction (see FIGS. 5A and 5B).

There is a wide latitude for the choice of materials and their thicknesses within the embodiments of the present application.

The semiconductor layers 14, 15 and 42 can be made of monocrystalline, polycrystalline and amorphous semiconductor material such as Si, Ge, GaAs, CdTe, Cu(In,Ga)Se₂, CdS, CdSe, Sb₂S₃, PbS, ZnTe and others. Thickness of the semiconductor layers can be in a range from about 2 nm to 500 μm.

The metal contacts 16 and 17 can be made of Al, Mo, W, Cr, Pt, Ta, Ti, Cu, TiN, their based alloys and laminates. Thickness of the metal contacts can be in a range from about 2 nm to 500 μm.

The antireflection layer 18 can be made of TiO₂, Si₃N₄, Al₂O₃, SiO₂, SiO, Ta₂O₅, ZnS, MgF₂ and other materials including their based multilayers. Thickness of the antireflection layer can be in a range from about 5 nm to 1 μm.

The magnetic layers 24 and 26 can be made of a magnetic material comprising Fe, Co, Ni, their based alloys and laminates, for example, CoFe, NiFe, CoNiFe, CoFeB, FePt, CoPd, (CoFe/Pt)n, (Co/Pd)n and others. Thickness of the magnetic layers 24 and 26 can be in a range from of about 0.2 nm to about 50 nm.

The isolative layer 25 can be made of dielectric and semiconductor materials such as AlₓO_{y}, SiOₓ, Si, C, TaₓO_{y}, TiₓO_{y}, MgO, AlN, HfₓO_{y}, NiₓO_{y}, VₓO_{y}, WₓO_{y}, ZrₓO_{y}, NbₓO_{y}, CuₓO, RuOₓ, CrₓO_{y}, SrTiO₃, BaTiO₃, PbZrTiO₃, PbLaTiO₃, perovskite-like materials, polyimide, Si, a:Si, poly-Si, Ge, SiC, SiGe, AlSb, AlAs, AN, AlP, BN, BP, BAs, GaSb, GaAs, GaN, GaP, InSb, InAs, InN, InP, AlₓGa_{1-X}As, InₓGa₁₋ₓAs, InGaP, AlInAs, AlInSb, GaAsN, GaAsP, AlGaN, AlGaP, InO₂, InGaN, InAsSb, InGaSb, AlGaInP, InAlGaP, InGaAlP, AlInGaP, AlGaAsP, InGaAsP, AlInAsP, AlGaAsN, InGaAsN, InAlAsN, GaAsSbN, GaInNAsSb, GaInAsSbP, CdSe, CdS, CdTe, ZnO, ZnO₂, ZnSe, ZnS, ZnTe, CdZnTe, HgCdTe, HgZnSe, CuCl, PbS, PbTe, SnTe, PbSnTe, Tl₂SnTe₅, Tl₂GeTe₅, Bi₂Te₃, Cd₃P₂, Cd₃As₂, Cd₃Sb₂, Zn₃P₂, Zn₃As₂, Zn₃Sb₂, SnO₂, In₂O₃, CdO, Cu₂O, InGaZnO, (In,Sn)₂O₃, ZnSnO, ZnO, InZnO AgSbO₃, 2CdO·GeO₂, 2CdO·PbO, CdS·In2Sₓ, MoO₃, (In,Sn)₂O₃/TiO₂, and/or similar materials, their based laminates, such as Ti/TiO₂/Ti, Ru/TiO₂/Ru, Ru/TaₓO_{y}/Ru, Cu/CuₓO/Cu, and others. Thickness of the isolative layer 25 can be in a range from about 0.2 nm to about 50 nm.

The conductive plate 27 and 28 can be made of a conductive material comprising a substantial conductivity such as Mo, W, Ti, Cr, Pt, TiN, PtSi, Al, Cu, Ag, Au, Ni, poli-Si and similar or their based alloys and/or laminates. Thickness of the conductive plates 27 and 28 can be in a range from about 0.5 nm to about 5 μm.

The spacer layer 62 can be made of a dielectric (Si_{X}O_{Y}, Al_{X}O_{Y}, Si_{X}N_{Y} or similar) or semiconductor (Si, Ge, or similar) material, or their based laminates. Thickness of the spacer layer 44 can be in a range from about 0.5 nm to about 1 μm.

It will be apparent to those skilled in the art that various modifications and variations can be made to the structures of the disclosed embodiments without departing from the scope or spirit of the application. In view of the foregoing, it is intended that the present application cover modifications and variations of this invention provided they fall within the scope of the following claims and their equivalents.

While the specification of this disclosure contains many specifics, these should not be construed as limitations on the scope of the disclosure or of what may be claimed, but rather as descriptions of features specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

It is understood that the above embodiments are intended to be illustrative, and not restrictive. Many other embodiments will be apparent to those of skill in the art upon reviewing the above description. The scope of the embodiments should be, therefore, determined with reference to the appended claims, along with the full scope of equivalents to which such claims are entitled.

While the disclosure has been described in terms of several exemplary embodiments, those skilled in the art will recognize that the disclosure can be practiced with modification within the spirit and scope of the appended claims. Specifically, one of ordinary skill in the art will understand that the drawings herein are meant to be illustrative, and the spirit and scope of the disclosure are not limited to the embodiments and aspects disclosed herein but may be modified.

What is claimed is:

1. A photovoltaic system comprising:
a solar cell;
a blocking device; and
a magnetic capacitor,
wherein the solar cell and the magnetic capacitor are stacked over each other; and
wherein the solar cell and the magnetic capacitor are electrically coupled to each other through the blocking device.

2. The photovoltaic system of claim 1, wherein the magnetic capacitor comprising:
a first conductive electrode;
a second conductive electrode;
an isolative layer disposed between the first and second conductive electrodes;
a first magnetic layer disposed between the first conductive electrode and the isolative layer and comprising a first magnetization direction;
a second magnetic layer disposed between the second conductive electrode and the isolative layer and comprising a second magnetization direction;
wherein the first and second magnetic layers are substantially magnetically exchange coupled to each other through the isolative layer; and
wherein the isolative layer comprises a substantial polarization.

3. The photovoltaic system of claim 2, wherein the first magnetization direction and the second magnetization direction are directed anti-parallel to each other.

4. The photovoltaic system of claim 2, wherein the first magnetization direction and the second magnetization direction are directed in parallel to each other.

5. The photovoltaic system of claim 2, wherein the first magnetic layer and the second magnetic layer comprising an in-plane anisotropy.

6. The magnetic capacitor of claim 2, wherein the first magnetic layer and the second magnetic layer comprising a perpendicular anisotropy.

7. The photovoltaic system of claim 2, wherein the isolative layer comprises a dielectric material.

8. The photovoltaic system of claim 2, wherein the isolative layer comprises a semiconductor material.

9. The photovoltaic system of claim 1, wherein the blocking device comprises a diode.

10. The photovoltaic system of claim 9, wherein the diode comprises a Schottky contact.

11. The photovoltaic system of claim 1, wherein the blocking device comprises a transistor.

12. A photovoltaic system comprising:
a solar cell;
a magnetic energy storage device; and
a blocking device,
wherein the solar cell and the energy storage device are stacked over each other; and
wherein the solar cell and the energy storage device are electrically coupled to each other by means of the blocking device.

13. The photovoltaic system of claim 12, wherein the magnetic energy storage device comprising:
a first magnetic capacitor; and
a second magnetic capacitor;
wherein the first magnetic capacitor and the second magnetic capacitor are stacked over each other and electrically coupled to each other.

14. The photovoltaic system of claim 13, further comprising a conductive spacer layer disposed between the first magnetic capacitor and the second magnetic capacitor.

15. The photovoltaic system of claim 13, further comprising an isolative spacer layer disposed between the first magnetic capacitor and the second magnetic capacitor.

16. The photovoltaic system of claim 13, wherein each of the first and second magnetic capacitors comprising:
a first magnetic layer comprising a first magnetization direction;
a second magnetic layer comprising a second magnetization direction directed anti-parallel to the first magnetization direction; and
an isolative layer disposed between the first and second magnetic layers.

17. The photovoltaic system of claim 16, wherein the first magnetic layer of the first magnetic capacitor is electrically coupled to the first magnetic layer of the second magnetic capacitor and the second magnetic layer of the first magnetic capacitor is electrically coupled to the second magnetic layer of the second magnetic capacitor.

18. The photovoltaic system of claim 16, wherein the second magnetic layer of the first magnetic capacitor is electrically coupled to the first magnetic layer of the second magnetic capacitor.

19. The photovoltaic system of claim 16, wherein at least one of the magnetic layers comprises a multilayer structure.

20. The photovoltaic system of claim 16, wherein the second magnetization direction is reversible.
